(19) United States
(12) Patent Application Publication
(10) Pub. No.: US 2014/0030892 A1
(43) Pub. Date: Jan. 30, 2014

(54) METHOD FOR MANUFACTURING SILICON CARBIDE SUBSTRATE

(71) Applicant: Sumitomo Electric Industries, Ltd., Osaka (JP)

(72) Inventors: Tsubasa HONKE, Itami-shi (JP); Kyoko OKITA, Itami-shi (JP)

(21) Appl. No.: 13/915,107

(22) Filed: Jun. 11, 2013

(30) Foreign Application Priority Data
Jul. 26, 2012 (JP) 2012-165794

(51) Int. Cl. H01L 21/04

(52) U.S. Cl. CPC H01L 21/0445
USPC 438/691

(57) ABSTRACT

A method for manufacturing a silicon carbide substrate includes the steps of: preparing an ingot made of silicon carbide; obtaining a silicon carbide substrate by cutting the ingot prepared; etching a silicon surface of the silicon carbide substrate; and polishing the etching surface of the silicon carbide substrate after etching the silicon carbide substrate. The step of etching a silicon surface of the silicon carbide substrate includes the step of removing silicon atoms, which form the silicon carbide, from an etching region using chlorine gas, the etching region including the etching main surface of the silicon carbide substrate.

### BACKGROUND OF THE INVENTION

1. Field of the Invention

The present invention relates to a method for manufacturing a silicon carbide substrate, more particularly, a method for manufacturing a silicon carbide substrate processed with high precision.

2. Description of the Background Art

In recent years, in order to achieve high breakdown voltage, low loss, and the like in a semiconductor device, silicon carbide has begun to be adopted as a material for the semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like.

In such a semiconductor device employing silicon carbide as its material, a substrate made of silicon carbide is used. The silicon carbide substrate can be obtained by, for example, cutting an ingot produced by growing a silicon carbide single crystal on a seed substrate by means of a sublimation recrystallizing method. Further, such a silicon carbide substrate is polished using diamond abrasive grains or the like in order to remove a damage layer, which is generated in the surface of the silicon carbide substrate when cutting the ingot. As a polishing method for effectively removing the damage layer generated in the surface of the silicon carbide substrate, for example, Japanese Patent Laying-Open No. 2009-283629 proposes a method in which a roughly polished surface of a silicon carbide substrate is oxidized and a resulting oxide film is removed from the surface through final polishing.

Such a silicon carbide substrate obtained by cutting the ingot has a large warpage due to influence of the damage layer generated in the surface thereof. Meanwhile, with the polishing method proposed in Japanese Patent Laying-Open No. 2009-283629, it is difficult to remove the damage layer to such an extent that the warpage of the substrate can be sufficiently reduced. The warpage of the substrate results in decreased precision of processing when polishing the silicon carbide substrate. This makes it difficult to obtain a silicon carbide substrate processed with high precision, disadvantageously.

### SUMMARY OF THE INVENTION

The present invention has been made in view of the foregoing problem, and has its object to provide a method for manufacturing a silicon carbide substrate processed with high precision.

A method for manufacturing a silicon carbide substrate in the present invention includes the steps of: preparing an ingot made of silicon carbide; obtaining a silicon carbide substrate by cutting the ingot prepared; etching one main surface of the silicon carbide substrate; and polishing the one main surface of the silicon carbide substrate after etching the silicon carbide substrate. The step of etching the one main surface of the silicon carbide substrate includes the step of removing silicon atoms, which form the silicon carbide, from an etching region using a gas including halogen atoms, the etching region being a region including the main surface of the silicon carbide substrate.

In the method for manufacturing the silicon carbide substrate in the present invention, before polishing the silicon carbide substrate, the silicon atoms forming the silicon carbide are removed from the etching region including the main surface of the silicon carbide substrate, thereby etching the main surface of the silicon carbide substrate. Accordingly, before polishing the silicon carbide substrate, warpage of the silicon carbide substrate can be reduced in advance. As a result, precision can be more improved in polishing the silicon carbide substrate. Thus, according to the method for manufacturing the silicon carbide substrate in the present invention, the silicon carbide substrate processed with high precision can be manufactured.

In the method for manufacturing the silicon carbide substrate, in the step of removing the silicon atoms, the silicon atoms forming the silicon carbide may be removed while carbon atoms forming the silicon carbide remain in the etching region. Accordingly, the warpage of the silicon carbide substrate can be reduced more securely.

In the method for manufacturing the silicon carbide substrate, the step of etching the one main surface of the silicon carbide substrate may further include the step of removing carbon atoms, which form the silicon carbide, from the etching region from which the silicon atoms have been removed, using an oxidizing gas after the step of removing the silicon atoms. Accordingly, the warpage of the silicon carbide substrate can be reduced further securely.

The method for manufacturing the silicon carbide substrate may further include the step of substituting the gas including the halogen atoms with an inert gas after the step of removing the silicon atoms and before the step of removing the carbon atoms. In this way, a reactant of the silicon atoms and the gas including the halogen atoms can be suppressed from reacting with oxidizing gas to generate a product.

In the method for manufacturing the silicon carbide substrate, in the step of removing the silicon atoms, the silicon atoms forming the silicon carbide may be removed from the etching region using chlorine gas or hydrogen chloride gas. As such, in the above-described step, the chlorine gas or hydrogen chloride gas suitable for etching of the silicon carbide substrate can be employed suitably.

In the method for manufacturing the silicon carbide substrate, the silicon carbide substrate obtained in the step of obtaining the silicon carbide substrate may have a diameter of 100 mm or more. Thus, the above-described method for manufacturing the silicon carbide substrate can be suitably employed in a method for manufacturing a silicon carbide substrate having a large diameter.

In the method for manufacturing the silicon carbide substrate, in the step of etching the one main surface of the silicon carbide substrate, the main surface of the silicon carbide substrate may be etched at a temperature of not less than 800° C. and not more than 1100° C. Thus, in the step, there can be employed a temperature condition under which the main surface of the silicon carbide substrate can be effectively etched.

In the method for manufacturing the silicon carbide substrate, in the step of etching the one main surface of the silicon carbide substrate, the main surface of the silicon carbide substrate may be etched at a pressure of not less than 1 Pa and less than 100 kPa. Thus, in the step, there can be employed a pressure condition under which the main surface of the silicon carbide substrate can be effectively etched.

As apparent from the description above, according to the method for manufacturing the silicon carbide substrate in the present invention, a silicon carbide substrate processed with high precision can be manufactured.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method for manufacturing a silicon carbide substrate.

FIG. 2 is a schematic view for illustrating the method for manufacturing the silicon carbide substrate.

FIG. 3 is a schematic view for illustrating the method for manufacturing the silicon carbide substrate.

FIG. 4 is a schematic view for illustrating the method for manufacturing the silicon carbide substrate.

FIG. 5 is a schematic view for illustrating the method for manufacturing the silicon carbide substrate.

FIG. 6 is a schematic view for illustrating the method for manufacturing the silicon carbide substrate.

FIG. 7 is a schematic view for illustrating the method for manufacturing the silicon carbide substrate.

FIG. 8 is a schematic view for illustrating the method for manufacturing the silicon carbide substrate.

FIG. 9 is a schematic view for illustrating the method for manufacturing the silicon carbide substrate.

FIG. 10 is a schematic view for illustrating the method for manufacturing the silicon carbide substrate.

FIG. 11 is a schematic view for illustrating the method for manufacturing the silicon carbide substrate.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly.

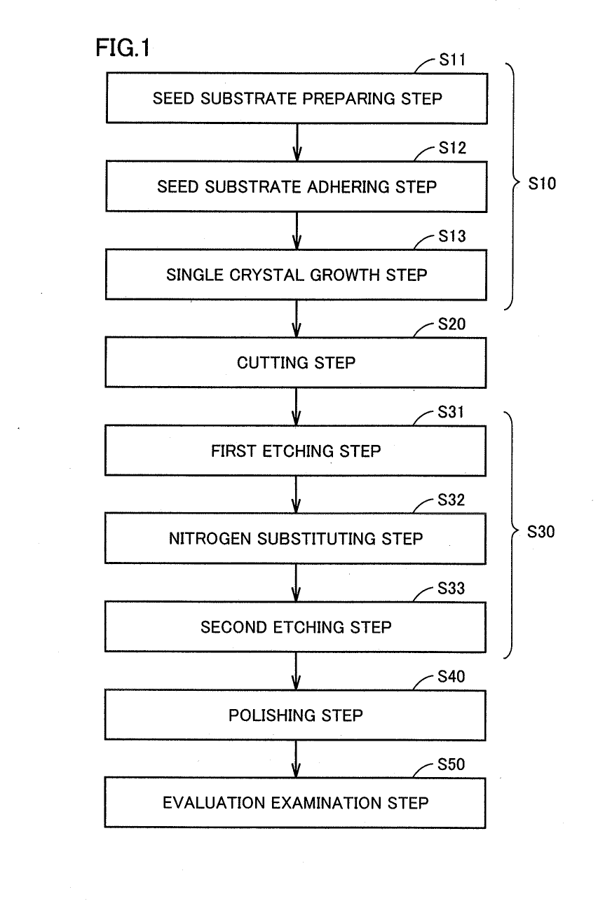

The following describes a method for manufacturing a silicon carbide substrate in one embodiment of the present invention. Referring to FIG. 1, first, as a step (S10), an ingot preparing step is performed. In this step (S10), steps (S11) to (S13) described below are performed to prepare an ingot made of silicon carbide.

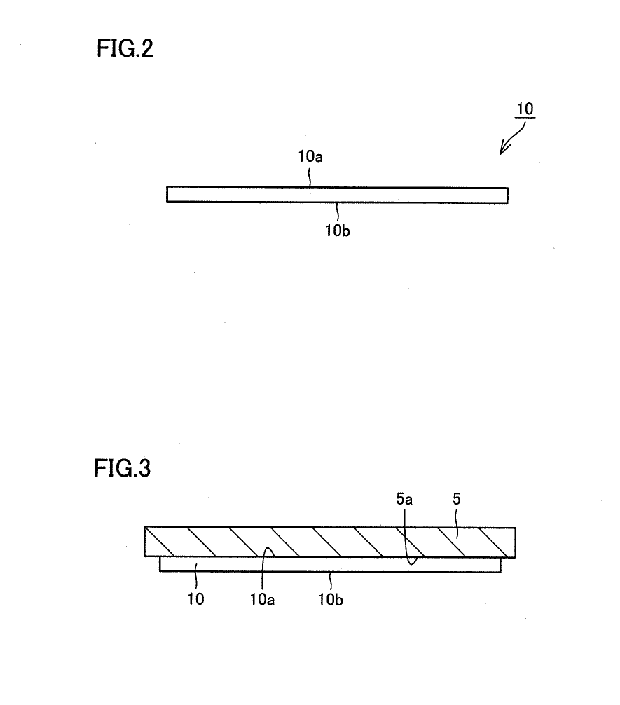

First, as step (S11), a seed substrate preparing step is performed. In this step (S11), referring to FIG. 2, a seed substrate 10 is prepared which has main surfaces 10a, 10b and which is made of silicon carbide. Seed substrate 10 has a shape of circular plate, and has a diameter of 100 mm or more, for example.

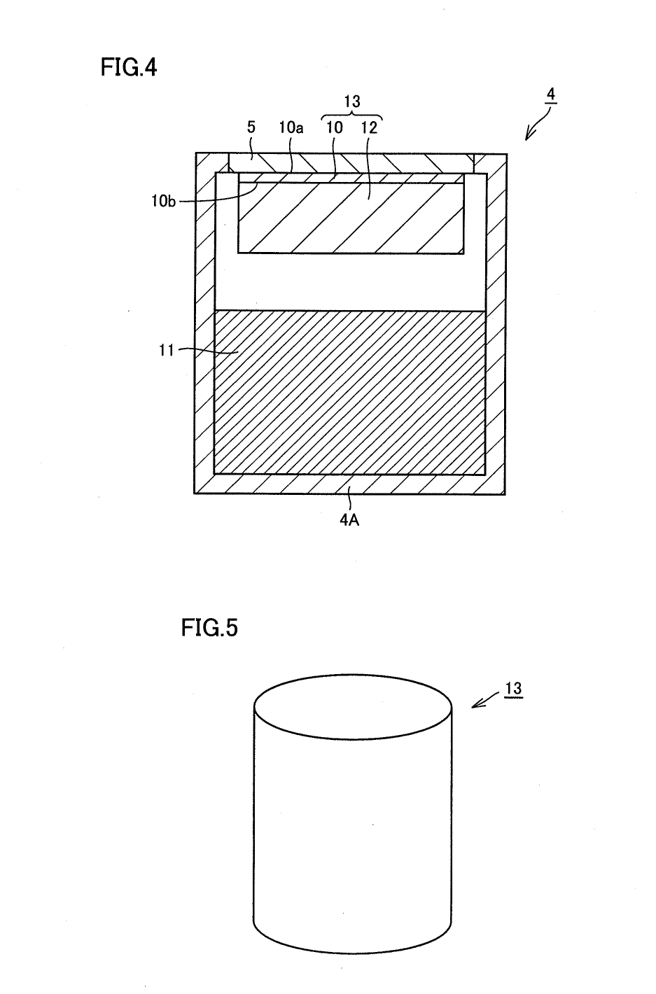

Next, as step (S12), a seed substrate adhering step is performed. In this step (S12), referring to FIG. 4, a cover member 5 is first detached from a crucible 4 made of carbon. Next, referring to FIG. 3, seed substrate 10 is adhered to cover member 5 such that main surface 10a faces a supporting surface 5a of cover member 5. Seed substrate 10 is adhered to cover member 5 using, for example, a carbon adhesive agent.

Next, as step (S13), a single crystal growth step is performed. In this step (S13), an ingot 13 is obtained by growing a silicon carbide single crystal film 12 on main surface 10b of seed substrate 10 in the following manner. Referring to FIG. 4, a powdery silicon carbide source material 11 is first contained in a crucible main body 4A. Next, cover member 5 having seed substrate 10 adhered thereon is placed onto crucible main body 4A. In this way, seed substrate 10 is placed in crucible 4 such that main surface 10b faces silicon carbide source material 11.

Next, while vacuuming crucible 4, temperature therein is increased to a predetermined temperature. Next, an inert gas such as argon (Ar) is introduced into crucible 4. Next, the temperature in crucible 4 is increased to a temperature at which a silicon carbide single crystal is grown (not less than 2000° C. and not more than 2400° C.). Next, crucible 4 is vacuumed to reduce the pressure to a predetermined pressure to start growth of silicon carbide single crystal film 12. In this way, silicon carbide single crystal film 12 is grown on main surface 10b of seed substrate 10, thus obtaining ingot 13.

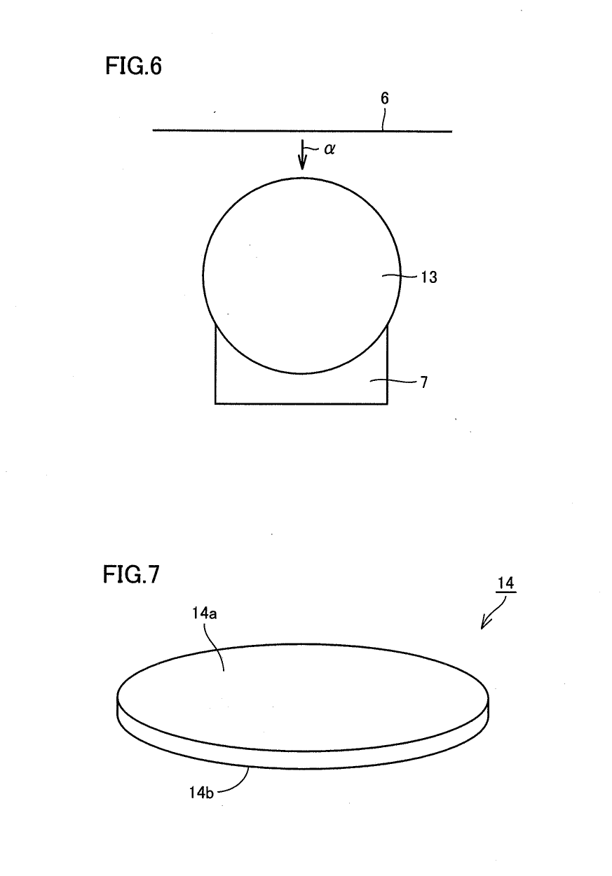

Next, as a step (S20), a cutting step is performed. In this step (S20), a silicon carbide substrate is obtained in the following manner by cutting ingot 13 prepared in the above-described step (S10). First, referring to FIG. 5 and FIG. 6, ingot 13 is first placed on a holder 7 with a portion of its side surface being supported by holder 7. Next, a wire 6 is moved to travel in a direction along the diameter direction of ingot 13 and approaches ingot 13 with wire 6 itself being along a cutting direction a perpendicular to the travel direction so as to bring wire 6 into contact with ingot 13. Then, by continuously advancing wire 6 with wire 6 itself being along cutting direction α, ingot 13 is cut. Accordingly, a silicon carbide substrate 14 shown in FIG. 7 is obtained.

Next, as a step (S30), an etching step is performed. In this step (S30), below-described steps (S31) to (S33) are performed, thereby etching a silicon (Si) surface 14b, which is one main surface of silicon carbide substrate 14 obtained in step (S20).

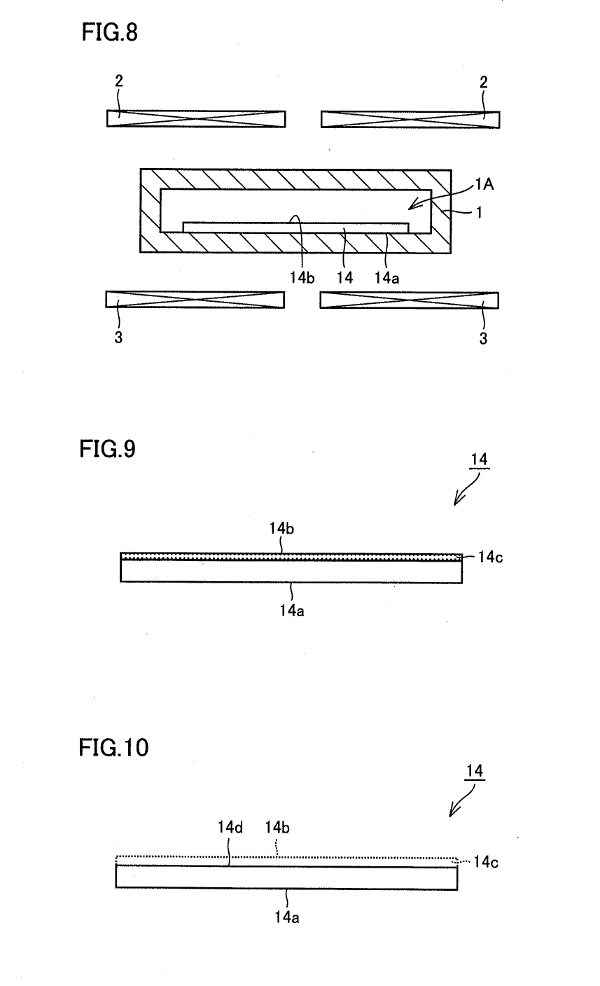

First, as a step (S31), a first etching step is performed. In this step (S31), referring to FIG. 8, silicon carbide substrate 14 is placed in an etching chamber 1A of a reaction tube 1 such that silicon surface 14b to be etched faces upward. Next, etching chamber 1A is vacuumed to a predetermined pressure. Next, while maintaining the vacuum state in etching chamber 1A, temperature in etching chamber 1A is increased to a temperature of not less than 800° C. and not more than 1100° C. using heaters 2, 3 disposed external to reaction tube 1.

Next, chlorine (Cl₂) gas, which includes halogen atoms, is introduced into etching chamber 1A via a gas inlet (not shown) of reaction tube 1, and is exhausted from a gas outlet (not shown). Etching chamber 1A is set to have a pressure of not less than 1 Pa and less than 100 kPa. By flowing the chlorine gas into etching chamber 1A in this way at a predetermined flow rate for a predetermined period of time, the following reaction takes place in silicon surface 14b of silicon carbide substrate 14: SiC+Cl₂→SiCl₄. Accordingly_{?} silicon (Si) atoms forming the silicon carbide of silicon carbide substrate 14 are selectively removed from an etching region 14c including silicon surface 14b of silicon carbide substrate 14 as shown in FIG. 9, with the result that carbon (C) atoms forming silicon carbide substrate 14 remain.

Next, as step (S32), a nitrogen substituting step is performed. In this step (S32), referring to FIG. 8, after vacuuming etching chamber 1A, nitrogen (N₂) gas, which is an inert gas, is introduced into etching chamber 1A via the gas inlet and is exhausted via the gas outlet. Accordingly, the chlorine gas and silicon tetrachloride (SiCl₄) gas remaining in etching chamber 1A after step (S31) is substituted with the nitrogen gas. It should be noted that the inert gas introduced into etching chamber 1A is not limited to the nitrogen (N₂) gas, and may be a noble gas such as argon (Ar), for example.

Next, as step (S33), a second etching step is performed. In this step (S33), first, with the temperature in etching chamber 1A being maintained at not less than 800° C. and not more than 1100° C., oxygen (O₂) gas, which is an oxidizing gas, is introduced into etching chamber 1A via the gas inlet and is exhausted via the gas outlet. Etching chamber 1A is set to have a pressure of not less than 1 Pa and less than 100 kPa. By flowing the oxygen gas into etching chamber 1A in this way at a predetermined flow rate for a predetermined period of time, the following reaction takes place in etching region 14c of silicon carbide substrate 14: SiC+O₂→SiC+CO₂. Accordingly, carbon atoms forming the silicon carbide of silicon carbide substrate 14 are removed from etching region 14c from which the silicon atoms have been removed. As a result, as shown in FIG. 10, etching region 14c is removed from silicon carbide substrate 14, thereby forming an etching surface 14d. Further, the oxidizing gas is not limited to the oxygen gas, and may be ozone (O₃) gas or hydrogen (H₂) gas, for example. By performing the above-described steps (S31) to (S33) in this way, silicon surface 14b of silicon carbide substrate 14 is etched, thus completing step (S30). In the present embodiment, the etching of silicon surface 14b of silicon carbide substrate 14 has been illustrated, but carbon surface 14a opposite to silicon surface 14b may be etched.

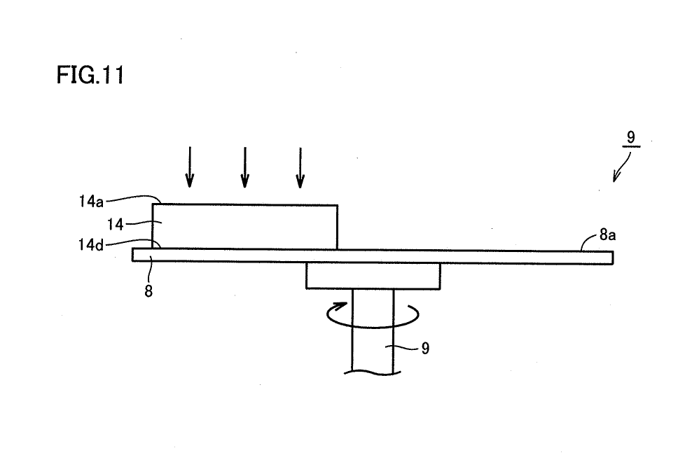

Next, as a step (S40), a polishing step is performed. In this step (S40), as described below, etching surface 14d is polished which is one main surface of silicon carbide substrate 14 having been etched in the above-described step (S30). Referring to FIG. 11, first, silicon carbide substrate 14 is disposed in a polishing apparatus 9 such that etching surface 14d to be etched is in contact with a polishing surface 8a of a rotary surface plate 8. On polishing surface 8a of rotary surface plate 8, for example, highly hard abrasive grains such as diamond abrasive grains are fixed. Next, while supplying slurry onto polishing surface 8a, a rotating shaft 9a is rotated at a predetermined rotating speed for a predetermined period of time. In doing so, as indicated by arrows in FIG. 11, a predetermined load is applied to silicon carbide substrate 14 from the carbon surface 14a side. In this way, etching surface 14d of silicon carbide substrate 14 is polished. In the present embodiment, it has been illustrated that etching surface 14d of silicon carbide substrate 14 is polished, but carbon surface 14a opposite to etching surface 14d may be polished or both etching surface 14d and carbon surface 14a may be polished.

Next, as a step (S50), an evaluation examination step is performed. In this step (S50), quality of silicon carbide substrate 14 is examined in terms of crystal defects and the like. By performing the above-described steps (S10) to (S50), silicon carbide substrate 14 is manufactured, thus completing the method for manufacturing the silicon carbide substrate in the present embodiment.

As described above, in the method for manufacturing the silicon carbide substrate in the present embodiment, before polishing silicon carbide substrate 14, the silicon atoms forming the silicon carbide are removed from etching region 14c including silicon surface 14b of silicon carbide substrate 14, thereby etching silicon surface 14b of silicon carbide substrate 14. Accordingly, before polishing silicon carbide substrate 14, warpage of silicon carbide substrate 14 can be reduced in advance. By reducing the warpage of silicon carbide substrate 14 to planarize the surface thereof in this way, precision can be more improved in adhering the surface of silicon carbide substrate 14 and polishing surface 8a of rotary surface plate 8 to each other when polishing silicon carbide substrate 14. As a result, precision can be more improved in polishing silicon carbide substrate 14. Thus, according to the method for manufacturing the silicon carbide substrate in the present embodiment, silicon carbide substrate 14 processed with high precision can be manufactured.

Further, in the present embodiment, the silicon atoms may be removed from etching region 14c by the chlorine gas in step (S31), but the present invention is not limited to this. For example, the silicon atoms may be removed from etching region 14c by hydrogen chloride (HCl) gas. As such, in step (S31), the chlorine gas or hydrogen chloride gas suitable for etching of silicon carbide substrate 14 can be employed suitably as the etching gas.

Further, as described above, in the present embodiment, step (S30) may further include step (S33) of removing carbon atoms after step (S31) of removing the silicon atoms. This step (S33) is not an essential step in the method for manufacturing the silicon carbide substrate in the present invention, but by performing step (S33), the warpage of silicon carbide substrate 14 can be reduced more securely.

Further, as described above, in the present embodiment, step (S32) of substituting the chlorine gas with the nitrogen gas may be performed after step (S31) and before step (S33). Accordingly, silicon tetrachloride gas generated in step (S31) can be suppressed from reacting with oxygen gas and generating silicon dioxide (SiO₂).

Further, in the present embodiment, in step (S20), silicon carbide substrate 14 having a diameter of 100 mm or more may be obtained. Thus, the method for manufacturing the silicon carbide substrate in the present embodiment can be suitably employed in a method for manufacturing a silicon carbide substrate having a large diameter.

Further, as described above, in the present embodiment, in step (S30), silicon surface 14b of silicon carbide substrate 14 may be etched at a temperature of not less than 800° C. and not more than 1100° C. Thus, in this step (S30), there can be employed a temperature condition under which silicon surface 14b of silicon carbide substrate 14 can be effectively etched.

Further, as described above, in the present embodiment, in step (S30), silicon surface 14b of silicon carbide substrate 14 may be etched at a pressure of not less than 1 Pa and less than 100 kPa. Thus, in step (S30), there can be employed a pressure condition under which silicon surface 14b of silicon carbide substrate 14 can be effectively etched.

Further, in the present embodiment, in step (S20), silicon carbide substrate 14 obtained by cutting ingot 13 may be beveled. In the method for manufacturing the silicon carbide substrate in the present embodiment, even if the beveling causes a damage layer in a surface of silicon carbide substrate 14, the damage layer can be readily removed in the subsequent etching step (S30).

### EXAMPLE

An experiment was conducted to confirm the effect of the present invention with regard to polishing precision depending on warpage of a silicon carbide substrate. First, a seed substrate made of silicon carbide was prepared. Next, a silicon carbide single crystal film was formed on the crystal growth surface of the seed substrate, thereby producing an ingot. Next, the ingot was cut, thereby obtaining a silicon carbide substrate having a diameter of 3 inches. Next, the silicon carbide substrate was placed in an etching chamber of a reaction tube such that the silicon (Si) surface to be etched faced upward. The etching chamber had a volume of 14 L. Next, the etching chamber was vacuumed to reduce pressure to 50 Pa. Next, while maintaining the vacuum state in the etching chamber, temperature therein was increased to 1000° C. Next, chlorine gas was introduced into the etching chamber. The chlorine gas was introduced at a flow rate of 0.3 L/min for 30 minutes. Next, the etching chamber was vacuumed and the gas in the etching chamber was substituted with nitrogen gas. Next, oxygen gas was introduced into the etching chamber. The oxygen gas was introduced at a flow rate of 2 L/min for 5 minutes. Then, a change in the thickness of the silicon carbide substrate and a change in SORI before and after the etching were inspected. Similar inspection was performed in the case where a carbon (C) surface of a silicon carbide substrate was etched.

The following describes a result of the experiment. First, the change in thickness of the silicon carbide substrate was 8 μm before and after etching the silicon surface, and was 20 μm before and after etching the carbon surface. Thus, in the method for manufacturing the silicon carbide substrate in the present invention, it was confirmed that the thickness of the silicon carbide was greatly changed by etching the silicon carbide substrate. Further, the SORI of the silicon carbide substrate before the etching was 11.4 μm, whereas the SORI of the silicon carbide substrate after the etching was improved to be 9.7 μm. Thus, in the method for manufacturing the silicon carbide substrate in the present invention, it was confirmed that precision in polishing can be more improved by reducing the warpage of the silicon carbide substrate.

The method for manufacturing the silicon carbide substrate in the present invention can be particularly advantageously applied to a method for manufacturing a silicon carbide substrate, which is required to manufacture a silicon carbide substrate processed with high precision.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing an ingot made of silicon carbide;
obtaining a silicon carbide substrate by cutting said ingot prepared;
etching one main surface of said silicon carbide substrate; and
polishing the one main surface of said silicon carbide substrate after etching said silicon carbide substrate,
the step of etching said one main surface of said silicon carbide substrate including the step of removing silicon atoms, which form said silicon carbide, from an etching region using a gas including halogen atoms, said etching region being a region including said main surface of said silicon carbide substrate.

2. The method for manufacturing the silicon carbide substrate according to claim 1, wherein
in the step of removing said silicon atoms, the silicon atoms forming said silicon carbide are removed while carbon atoms forming said silicon carbide remain in said etching region.

3. The method for manufacturing the silicon carbide substrate according to claim 1, wherein
the step of etching said one main surface of said silicon carbide substrate further includes the step of removing carbon atoms, which form said silicon carbide, from said etching region from which the silicon atoms have been removed, using an oxidizing gas after the step of removing said silicon atoms.

4. The method for manufacturing the silicon carbide substrate according to claim 3, further comprising the step of substituting the gas including said halogen atoms with an inert gas after the step of removing said silicon atoms and before the step of removing said carbon atoms.

5. The method for manufacturing the silicon carbide substrate according to claim 1, wherein
in the step of removing said silicon atoms, the silicon atoms forming said silicon carbide are removed from said etching region using chlorine gas or hydrogen chloride gas.

6. The method for manufacturing the silicon carbide substrate according to claim 1, wherein
said silicon carbide substrate obtained in the step of obtaining said silicon carbide substrate has a diameter of 100 mm or more.

7. The method for manufacturing the silicon carbide substrate according to claim 1, wherein
in the step of etching said one main surface of said silicon carbide substrate, said main surface of said silicon carbide substrate is etched at a temperature of not less than 800° C. and not more than 1100° C.

8. The method for manufacturing the silicon carbide substrate according to claim 1, wherein
in the step of etching said one main surface of said silicon carbide substrate, said main surface of said silicon carbide substrate is etched at a pressure of not less than 1 Pa and less than 100 kPa.
